(19) United States
(12) Patent Application Publication
(10) Pub. No.: US 2008/0119018 A1
(43) Pub. Date: May 22, 2008

(54) Image display unit and method for manufacturing the same

(75) Inventors: Yoshiaki Toyota, Hachioji (JP); Takeshi Sato, Kokubunji (JP); Hajime Akimoto, Kokubunji (JP)

Correspondence Address: Stanley P. Fisher;Reed Smith Hazel & Thomas LLP, Suite 1400, 3110 Fairview Park Drive, Falls Church, VA, 22042-4503, US

(73) Assignee: Hitachi Displays, Ltd..

(21) Appl. No.: 11/979,515

(22) Filed: Nov. 5, 2007

(30) Foreign Application Priority Data
Nov. 21, 2006 (JP) 2006-314064

(51) Int. Cl. H01L 21/84

(52) U.S. Cl. 438/164; 257/E21.7

(57) ABSTRACT

The present invention provides an image display unit and a method for manufacturing the same, in which the number of photolithographic processes can be reduced in the manufacture of an active substrate, and the manufacturing cost can be decreased. In a bottom gate type TFT substrate, a transparent conductive film 16 in the same layer as a pixel electrode 3 is used as a bottom layer, said pixel electrode 3 having said gate electrode 4 on main surface of an insulating substrate 1, and a laminated electrode film with a metal film 26 superimposed on a top layer thereof, and said pixel electrode 3 is used as the transparent conductive film 16.

### BACKGROUND OF THE INVENTION

1. Field of the Invention

The present invention relates to an image display unit and a method for manufacturing the same. In particular, the invention relates to an image display unit such as a liquid crystal display unit or an organic electroluminescence display unit with an active substrate having a multiple of pixels, which are made up by thin-film transistor and are disposed on main surface of an insulating substrate.

2. Description of the Prior Art

As an image display unit called “a flat panel display (FPD)” such as a liquid crystal display unit or an organic electroluminescence display unit, an active matrix type display unit with a thin-film transistor (TFT) circuit for each pixel is now widely propagated. A substrate with such thin-film transistor circuit disposed thereon is also called an active matrix substrate or an active substrate or is simply referred as a TFT substrate.

In the manufacture of the TFT substrate as described above, a number of photolithographic processes are used (also called “photo-etching processes”). In the photolithographic process, a number of processes are needed such as coating of photosensitive resist and drying, exposure to ultraviolet light or the like using an exposure mask, developing, etching, rinsing, etc. The manufacture of exposure mask and the facilities to be used in the photolithographic process requires high cost, and much time is also required for the processing in the photolithographic process. The manufacture of the TFT substrate at lower cost is an important problem, which exerts direct influence on the production of the image display unit at lower cost. For this purpose, it is essential to reduce the number of photolithographic processes.

For the reduction of the number of photolithographic processes in this technical field, the Patent Document 1 discloses a process in the manufacture of a bottom gate type TFT substrate (active matrix substrate), according to which ITO (indium tin oxide) and chromium (Cr) film are laminated on a glass substrate, which is an insulating substrate, and a Cr/ITO laminated film is produced by exposing the same resist to light for two times.

[Patented Document 1] JP-A-6-317809

### SUMMARY OF THE INVENTION

According to the disclosure of the Patent Document 1, it is necessary to perform the photolithographic processes for five times in order to manufacture the TFT substrate. Also, when a thin-film transistor circuit such as driver circuit in the periphery of pixel area or an organic electroluminescence (OLED) pixel circuit is prepared on the insulating substrate. One more photolithographic process must be added to ensure good contact between these circuits and scan lines (gate lines) or a source-drain electrode. According to the prior art, it is difficult to extensively decrease the manufacturing cost of the image display unit by reducing the number of photolithographic processes.

It is an object of the present invention to provide an image display unit and a method for manufacturing the same, by which it is possible to reduce the number of photolithographic processes and to decrease the manufacturing cost by introducing new idea and procedure on the arrangement of thin-film, which constitutes the electrode and the insulating film, and on the procedure of processing.

To attain the above object, the present invention provides an image display unit with a bottom gate type TFT substrate, wherein the gate electrode is a laminated film having a transparent conductive film in the same layer as a pixel electrode made of a transparent conductive film on main surface of said insulating substrate as a lower layer, said gate electrode being a laminated film with a metal film superimposed on an upper layer thereof, and said pixel electrode is said transparent conductive film.

Also, the present invention provides the image display unit as described above, wherein there is provided a metal film for connection in the same layer of said metal film on a part of upper end edge of said pixel electrode, and said source-drain electrode is electrically connected to said transparent conductive film to constitute said pixel electrode via said metal film for connection.

Further, the present invention provides the image display unit as described above, wherein said laminated film, together with a gate insulating film deposited on a top layer of said gate electrode, a semiconductor film positioned on a top layer of said insulating film and a part of said source-drain electrode, constitutes a storage capacitor of pixel.

Also, the present invention provides a method for manufacturing an image display unit, wherein a gate electrode and a pixel electrode are prepared by using laminated electrode film structure where a metal electrode is deposited on a transparent conductive film made of ITO or the like. When a source-drain electrode of a thin-film transistor is processed, the metal electrode on a top layer is removed at the same time, and the pixel electrode is prepared by the transparent conductive film.

Further, the present invention provides the method for manufacturing an image display unit as described above, wherein said gate insulating film and said semiconductor film formed on a top layer of said laminated electrode film and a storage capacitor formed with said metal film are prepared on said pixel area.

According to the method for manufacturing an image display unit of the present invention, the pixel electrode can be prepared at the same time when the source-drain electrode is processed. The active substrate of a liquid crystal display unit can be manufactured by four photolithographic processes, and an active substrate of the organic electroluminescence display unit can be manufactured by five photolithographic processes. As a result, it is possible to manufacture the image display unit at lower cost.

The present invention is not limited to the manufacture of the liquid crystal display unit or an organic electroluminescence display unit with counter electrode on the color filter substrate as described above, and the invention can be applied to the other types of liquid crystal display unit and to the image display unit based on other driving concept using the active substrate.

### BRIEF DESCRIPTION OF THE DRAWINGS

FIG. 1 represents cross-sectional views each showing an essential portion of a pixel, which constitutes a liquid crystal display unit to explain the Embodiment 1 of an image display unit according to the present invention;

FIG. 2 is an equivalent circuit diagram to explain an arrangement of the liquid crystal display unit made up by the pixels as shown in FIG. 1;

FIG. 3 is a plan view of a pixel shown in FIG. 2;

FIG. 4 represents process drawings to explain a method for manufacturing the liquid crystal display unit of the Embodiment 1 of the invention;

FIG. 5 represents process drawings similar to those of FIG. 4 to explain a method for manufacturing the liquid crystal display unit in the Embodiment 1 of the invention;

FIG. 6 represents process drawings similar to those of FIG. 5 to explain a method for manufacturing the liquid crystal display unit in the Embodiment 1 of the invention;

FIG. 7 represents process drawings similar to those of FIG. 6 to explain a method for manufacturing the liquid crystal display unit in the Embodiment 1 of the invention;

FIG. 8 represents process drawings similar to those of FIG. 7 to explain a method for manufacturing the liquid crystal display unit in the Embodiment 1 of the invention;

FIG. 9 represents cross-sectional views each showing an essential portion of a pixel to constitute an organic electroluminescence display unit to explain the Embodiment 2 of the image display unit of the invention;

FIG. 10 is an equivalent circuit diagram to explain an arrangement of the organic electroluminescence display unit, which is made up by pixels shown in FIG. 9;

FIG. 11 is a plan view of a pixel shown in FIG. 10;

FIG. 12 represents cross-sectional views each showing an essential portion of a pixel to constitute a liquid crystal display unit to explain the Embodiment 3 of the image display unit of the invention;

FIG. 13 is a plan view of a pixel in the Embodiment 3 of the invention;

FIG. 14 represents process drawings to explain a method for manufacturing the liquid crystal display unit according to the Embodiment 3 of the invention;

FIG. 15 represents process drawings similar to those in FIG. 14 to explain the method for manufacturing the liquid crystal display unit according to the Embodiment 3 of the invention;

FIG. 16 represents process drawings similar to those in FIG. 15 to explain the method for manufacturing the liquid crystal display unit according to the Embodiment 3 of the invention;

FIG. 17 represents process drawings similar to those in FIG. 16 to explain the method for manufacturing the liquid crystal display unit according to the Embodiment 3 of the invention;

FIG. 18 represents cross-sectional views each showing an essential portion of a pixel, which constitutes an organic electroluminescence display unit to explain the Embodiment 4 of the image display unit of the invention; and

FIG. 19 is a plan view to explain an arrangement of a pixel in the Embodiment 4 of the image display unit of the invention.

### DESCRIPTION OF THE PREFERRED EMBODIMENTS

Detailed description will be given below on the best aspect of the invention referring to the embodiments and the attached drawings.

### Embodiment 1

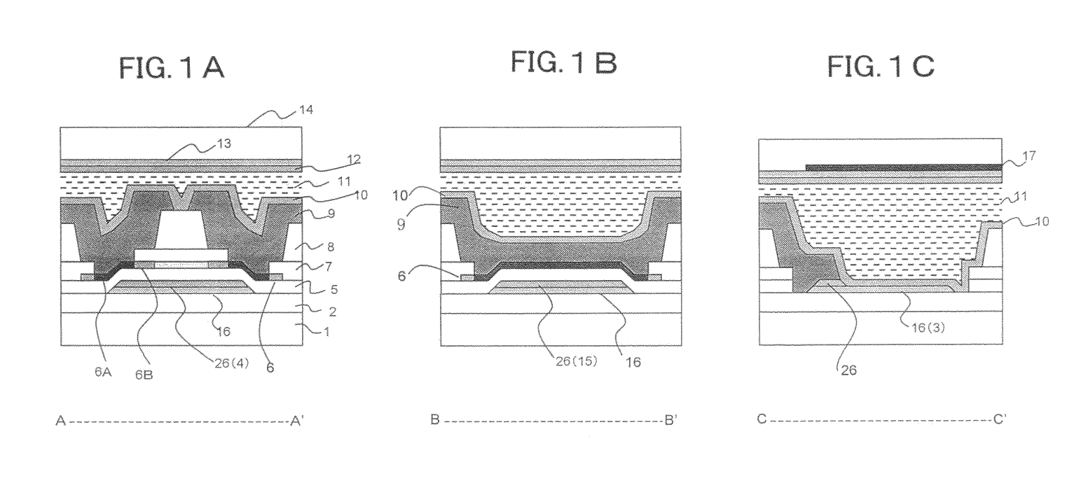

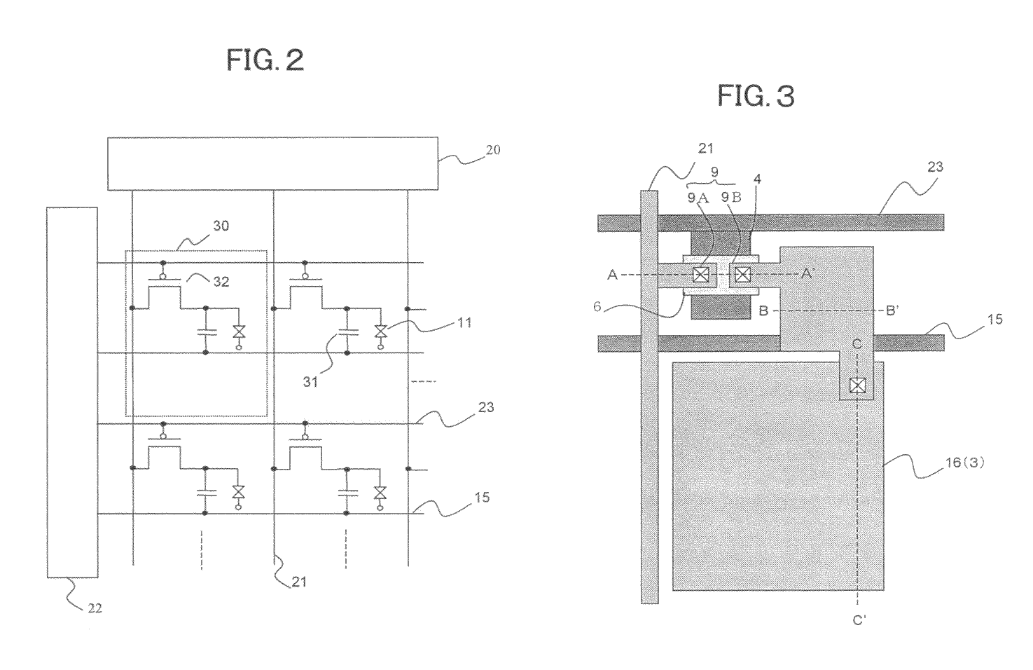

FIG. 1 represents cross-sectional views each showing an essential portion of a pixel to constitute a liquid crystal display unit to explain the Embodiment 1 of an image display unit according to the present invention. This liquid crystal display unit comprises an active substrate (thin-film transistor substrate; TFT substrate), a counter substrate (a color filter substrate when color filter is provided on it; CF substrate), and a liquid crystal layer interposed between the substrates. FIG. 1(a) represents a cross-sectional view of a thin-film transistor portion, FIG. 1(b) represents a cross-sectional view of a storage capacitor portion, and FIG. 1(c) represents a cross-sectional view of a pixel electrode portion. FIG. 2 is an equivalent circuit diagram to explain an arrangement of a liquid crystal display unit, which is constituted by the pixels shown in FIG. 1. FIG. 3 is a plan view of a pixel shown in FIG. 2. FIG. 1(a) is a cross-sectional view along the line A-A′ in FIG. 3, FIG. 1(b) is a cross-sectional view along the line B-B′ in FIG. 3, and FIG. 1(c) is a cross-sectional view along the line C-C′ in FIG. 3.

In the Embodiment 1, a glass substrate is used as the substrate. In FIG. 1, an underlying film (a buffer layer) 2 is disposed on main surface of a glass substrate 1 (a surface where the thin-film transistor or the like is prepared; inner surface). The underlying film 2 is a silicon oxide film, or a silicon nitride film, or a laminated film composed of silicon oxide film and silicon nitride film. When silicon nitride film is used, or when silicon nitride film is used as a lower layer and silicon oxide film is laminated on it as an upper layer, it is possible to prevent the deterioration of the characteristics when impurities (ions) from inside the glass substrate 1 enter and are diffused into the gate insulating film or into the liquid crystal. Unless otherwise specified, the glass substrate 1 where the underlying film 2 is deposited is referred simply as “substrate”.

In the thin-film transistor shown in FIG. 1(a), a gate electrode 4 is disposed on the substrate. The gate electrode 4 is made of a laminated electrode film, which comprises a transparent electrode 16 made of ITO and a metal electrode (aluminum in this case) 26 laminated on the transparent electrode. A gate insulating film 5 is provided on the entire surface of the substrate including the gate electrode 4, and a polycrystalline silicon (p-Si) film of island-like shape (silicon island) 6 to constitute an active layer of the thin-film transistor is prepared on it. On the polycrystalline silicon film 6, there are arranged a first interlayer insulating film 7 and a second interlayer insulating film 8. A source electrode and a drain electrode of a source-electrode electrode 9 are connected to a highly-doped p-type impurity area 6A of the polycrystalline silicon film 6 via a contact hole formed on each side of the first interlayer insulating film 7 and the second interlayer insulating film 8 respectively.

The source electrode and the drain electrode are insulated and separated by the second interlayer insulating film 8. Because the source electrode and the drain electrode are changed over during operation, these two electrodes are referred together as a source-drain electrode. A lightly-doped p-type impurity area 6B is disposed on inner sides of the highly-doped p-type impurity area 6A on both sides of the polycrystalline silicon film 6. A first orientation film 10 is coated on its top layer, and liquid crystal orientation control ability is given to it by the processing such as rubbing. Although not shown in the figure, a passivation film (PAS film) may be formed on a bottom layer of the first orientation film 10, depending on the case.

A counter electrode 13, which is a transparent electrode preferably made of ITO, is disposed on main surface of a transparent insulating substrate (glass substrate in this case) 14, and a second orientation film 12 is coated on it. Liquid crystal orientation control ability is given to it by the processing such as rubbing. Although not shown in the figure, a protective smooth film (overcoating film) may be formed on the bottom layer of the second orientation film 12, or more preferably, between a color filter (to be described later) and the counter electrode 13, depending on the case.

In the storage capacitor portion shown in FIG. 1(b), a storage capacitor (Cst) is prepared, which comprises a gate insulating film 5 and a polycrystalline silicon film 6 interposed between two electrodes. One of the electrodes is a laminated film made of a metal electrode 26 laminated on the transparent electrode 16, and the other of the electrodes is a metal film in the same layer as the source-drain electrode 9. The laminated film in this portion is in the same layer as the laminated film, which constitutes the gate electrode in the thin-film transistor shown in FIG. 1(a).

In the pixel electrode portion shown in FIG. 1(c), a pixel electrode 3 is made up by a gate electrode in the thin-film transistor portion of FIG. 1(a) and a transparent electrode 16 preferably made of ITO and constituting the bottom layer of the laminated film, which is in the same layer as one of the electrodes in the storage capacitor portion in FIG. 1(b). At an end of the transparent electrode 16, which makes up the pixel electrode 3, the aluminum film 26, which is the top layer of the laminated electrode film, remains as a connecting electrode, and the source-drain electrode 9 is electrically connected to the pixel electrode 3 via this connecting electrode.

On main surface of the counter substrate of the pixel electrode portion, a color filter 17 is disposed on the bottom layer of the counter electrode 13. It is preferable that a light shielding film is provided on a lateral end (between the color filter and the adjacent color filter) of the color filter 17 on peripheral region of the pixel electrode portion, although it is not shown in FIG. 1.

The first orientation film 10 of the TFT substrate is disposed to face and is attached to a second orientation film 12 of the counter substrate. A liquid crystal 11 is sealed in a cell gap between these two, and a liquid crystal display unit is prepared.

In the example of arrangement shown in FIG. 2, the pixel 30 comprises a thin-film transistor (TFT) 32, a storage capacitor 31 and the liquid crystal 11, and a plurality of pixels are arranged in two-dimensional matrix form. One of the source-drain electrodes of TFT 32 is connected to a signal line 21, which is drawn out from a drain driver (signal line driver circuit; data line driver circuit) 20. Also, the gate electrode of the TFT 32 is connected to a gate line (scan line) 23, which is drawn out from a gate driver (scan line driver circuit) 22. To a capacity line 15 drawn out from the gate driver 22, one of the electrodes of the storage capacitor (Cst) 31 is connected.

Display data to be supplied to the pixel 30 as selected according to scan signals sequentially given to the gate line 23 via the signal line 21 is accumulated in the storage capacitor (Cst) 31, and voltage is applied on the pixel electrode, and the liquid crystal 11 is turned on (orientation direction of the liquid crystal molecules is controlled).

FIG. 3 is a plan view to explain arrangement of a pixel shown in FIG. 2 on the substrate. In FIG. 3, the same functional component as in FIG. 2 is referred by the same symbol. A TFT to constitute the pixel is provided near the intersection of the signal line 21 and the gate line 23. One electrode 9A of the source-drain electrode 9 is connected to the signal line 21, and the other electrode 9B is connected to ITO 16, which constitutes the pixel electrode 3. The gate electrode 4 of the TFT is connected to the scan line 23. The capacitor line 15 is positioned on the bottom layer of the other electrode 9B of the source-drain electrode 9, and this forms the storage capacitor (Cst).

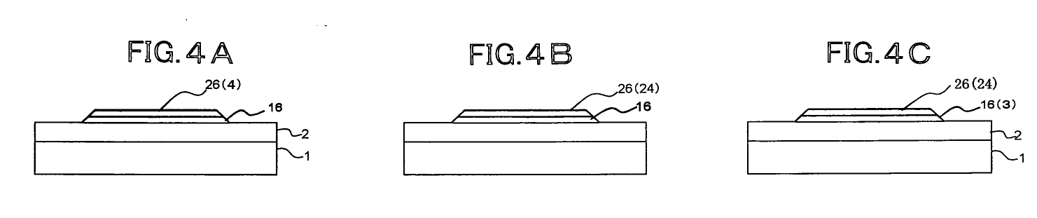

Referring to FIG. 4 to FIG. 8, description will be given below on a method for manufacturing a liquid crystal display unit according to the Embodiment 1 of the invention. In each of FIG. 4 to FIG. 8, Figs. (a), (b) and (c) each represents a cross-section of a thin-film transistor portion, a storage capacitor portion, and a pixel electrode portion respectively. It is needless to say that concrete numerical values in the description given below represents merely an example.

In FIGS. 4(a), 4(b) and 4(c), an underlying film 2 made of silicon oxide is deposited in film thickness of 300 nm on the glass substrate 1. ITO is deposited in film thickness of 100 nm as the transparent conductive film 16. On it, aluminum (Al) is deposited in film thickness of 150 nm as a metal film 26, and a laminated film (a laminated electrode film) is formed. A photosensitive resist is coated on the laminated electrode film and is dried, and a resist pattern is prepared by mask exposure and developing. By performing etching on it, a laminated electrode film of predetermined pattern is prepared on each of the gate electrode portion, the storage capacitor portion and the pixel electrode portion (photolithographic process 1).

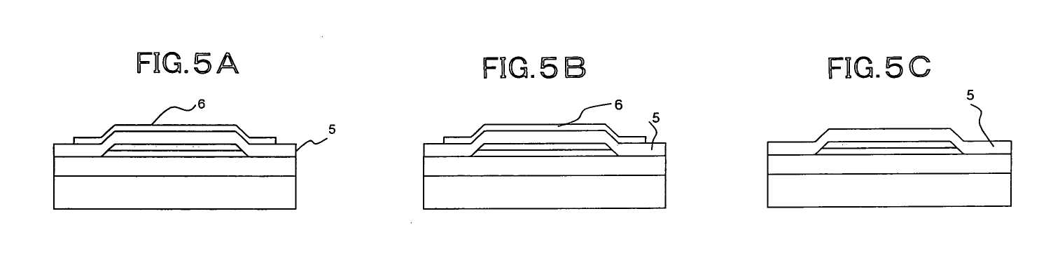

In FIGS. 5(a), (b) and (c), the gate insulating film 5 made of silicon oxide is deposited in film thickness of 100 pm to cover the laminated electrode film with the predetermined pattern. Next, amorphous silicon is disposed in film thickness of 50 nm. This is crystallized by laser annealing to reform it to a polycrystalline silicon film. On it, a photosensitive resist is coated and is dried, and resist pattern is formed by mask exposure and developing. After performing the etching, an island-like polycrystalline silicon semiconductor film 6 is prepared (photolithographic process 2). In this photolithographic process 2, the polycrystalline silicon semiconductor film of the pixel electrode portion is completely removed as shown in FIG. 5(c).

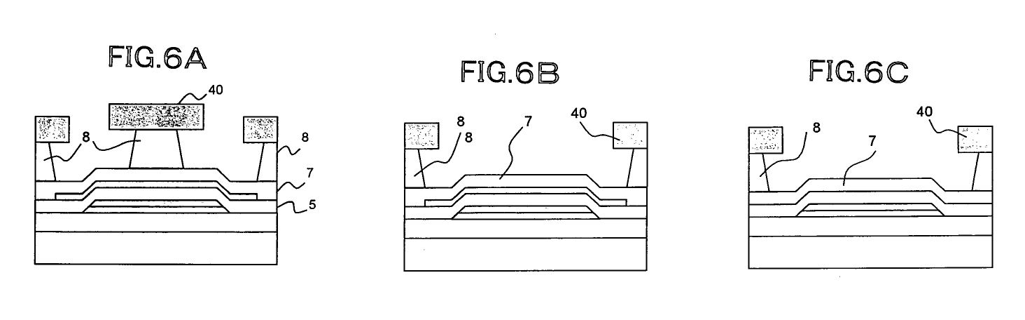

In FIGS. 6(a), (b) and (c), the first interlayer insulating film made of silicon oxide is deposited in film thickness of 100 nm to cover the gate insulating film 5 and the polycrystalline silicon semiconductor film 6. Further, the second interlayer insulating film made of silicon nitride is deposited in film thickness of 500 nm. By coating the photosensitive resist and drying, and by mask exposure and developing, a resist pattern 40 is formed. By using this resist pattern 40 as a mask, only the second interlayer insulating film 8 is processed (photolithographic process 3). In this case, the second interlayer insulating film 8 is reduced in size with respect to the resist pattern 40.

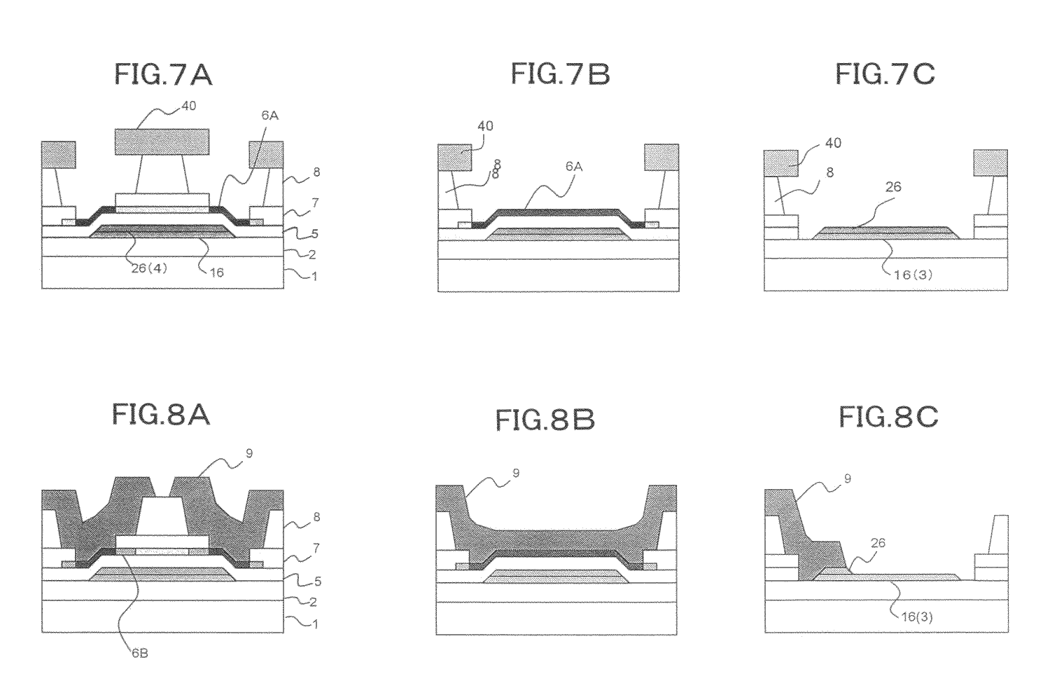

In FIGS. 7(a), (b) and (c), by ion implantation using the resist pattern 40 as a mask, a highly-doped p-type impurity area is prepared on the TFT portion and the storage capacitor portion. Then, using the resist as a mask, the first interlayer insulating film 7 and the gate insulating film 5 are removed (this is shown in FIG. 7). This ensures good contact of the gate electrode 4 and the source-drain electrode (to be described later). On the pixel portion, the first interlayer insulating film 7 and the gate insulating film 5 are completely removed as shown in FIG. 7(c).

In FIGS. 8(a), (b) and (c), the resist pattern 40 is removed. By ion implantation, a lightly-doped p-type impurity area 6B is prepared on both inner sides of the highly-doped p-type impurity area 6A. Next, the source-drain electrode made of aluminum is prepared in film thickness of 500 nm. On it, a photosensitive resist is coated and is dried. After mask exposure and developing, a resist pattern is formed. Using this resist pattern as a mask, the source-drain electrode 9 (FIG. 8(a)), the other of the electrodes of the storage capacitor (FIG. 8(b)), and the connecting electrode of the pixel electrode (FIG. 8(c)) are processed (photolithographic process 4).

The source-drain electrode is removed, and at the same time, a gate electrode material (aluminum film 26) on a top layer of ITO, which constitutes the pixel electrode 3, is removed except the connecting electrode potion. The source-drain electrode and the top electrode 26 of the pixel electrode are made of the same metal material (aluminum in this case), and these can be removed at the same time by using the same etching solution. In case the source-drain electrode and the top electrode of the pixel electrode 3 are made of different metal materials, after the processing of the source-drain electrode, the source-drain electrode is used as a mask, and by using an etching solution, which dissolves the top electrode of the pixel electrode portion and does not dissolve the source-drain electrode material, the top electrode 26 of ITO 16, i.e. the bottom layer of the pixel electrode 3, should be removed.

The first orientation film is formed to cover the entire region including the pixel electrode 3 and the source-drain electrode 9. A liquid crystal is filled in a gap between the first orientation film and the counter substrate where the color filter, the counter electrode and the second orientation film are formed, and the liquid crystal display unit as explained in connection with FIG. 1 is prepared. Depending on the case, a passivation film (PAS film) may be prepared on the bottom layer of the first orientation film 10 except the pixel electrode portion. Also, a protective smooth film (overcoating film) may be formed on the counter substrate between the bottom layer of the second orientation film 12 (more preferably the color filter) and the counter electrode 13.

In the Embodiment 1, there is a lightly-doped p-type impurity layer on the polycrystalline silicon film, which constitutes an active layer of TFT, and off-current on the thin-film transistor TFT can be reduced and the contrast can be increased. In the storage capacitor portion, a semiconductor layer (polycrystalline silicon layer) is present between the gate electrode and the source-drain electrode. Because highly-doped impurities are implanted in the semiconductor layer, the influence of parasitic capacity on the semiconductor layer can be decreased. As a result, the TFT substrate can be prepared through four photolithographic processes in the Embodiment 1, and the liquid crystal display unit can be manufactured at lower cost. Further, in case an underlying film is prepared on the glass substrate and a pixel electrode is disposed on this underlying film, the pixel electrode with superb flatness can be obtained and uneven color distribution due to unevenness of cell gap can be reduced.

### Embodiment 2

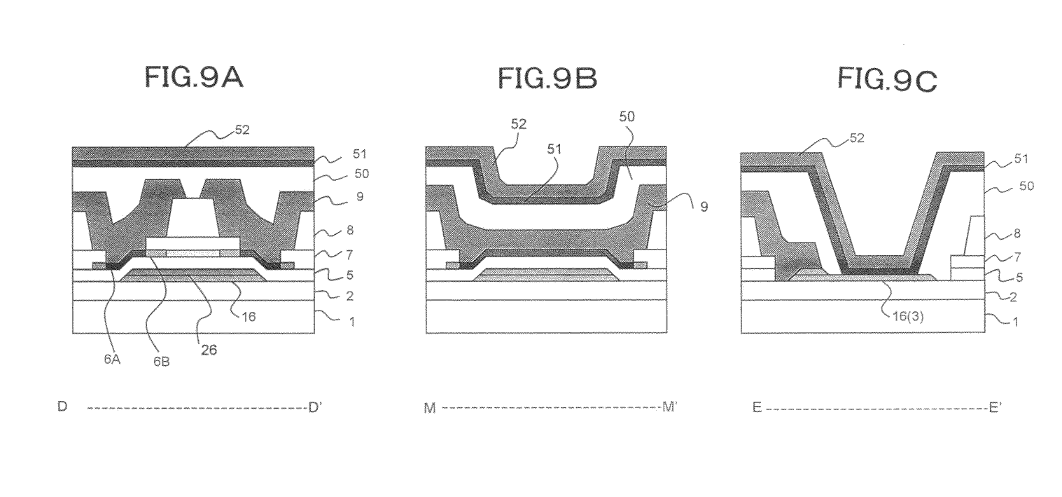

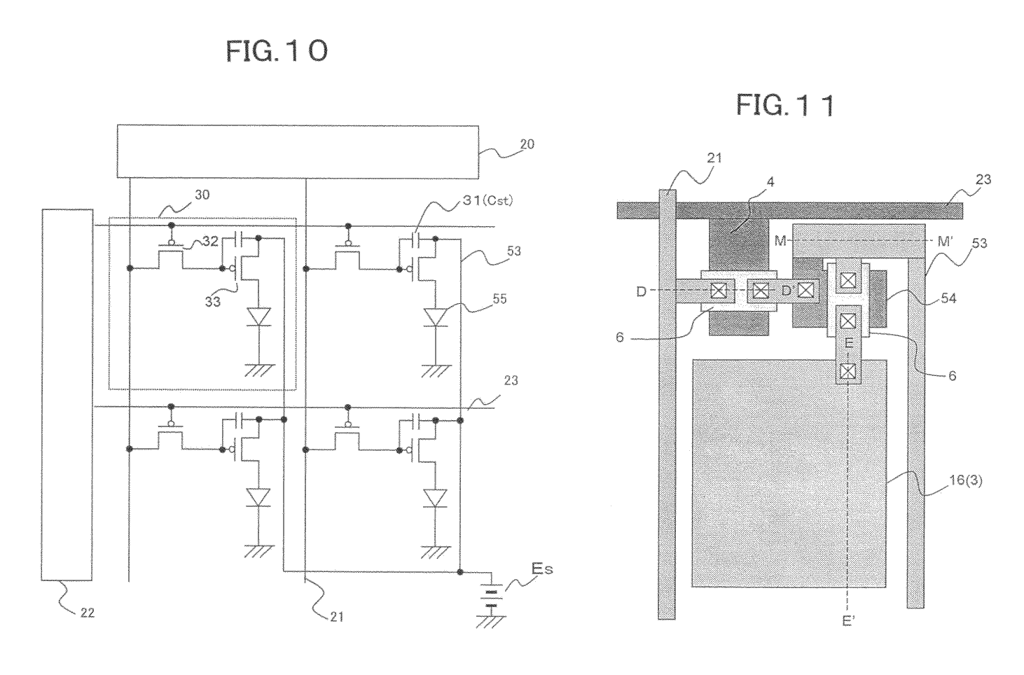

FIG. 9 represents cross-sectional views each showing an essential portion of a pixel, which constitutes an organic electroluminescence display unit to explain the Embodiment 2 of an image display unit of the present invention. The organic electroluminescence display unit (also called “OLED” (organic light emitting display)) comprises an organic electroluminescence light emitting layer on the top layer of an active substrate (thin-film transistor substrate; TFT substrate). FIG. 9(a) is a cross-sectional view of the thin-film transistor portion. FIG. 9(b) is a cross-sectional view of a storage capacitor portion, and FIG. 9(c) is a cross-sectional view of a pixel electrode portion. FIG. 10 is an equivalent circuit diagram to explain an arrangement of an organic electroluminescence display unit made up by pixels shown in FIG. 9. FIG. 11 is a plan view of a pixel shown in FIG. 10. FIG. 9(a) is a cross-sectional view along the line D-D′ in FIG. 11. FIG. 9(b) is a cross-sectional view along the line M-M′ in FIG. 11. FIG. 9(c) is a cross-sectional view along the line E-E′ in FIG. 11.

In the Embodiment 2, similarly to the Embodiment 1, a thin-film transistor (TFT), a storage capacitor (Cst) and a pixel electrode are prepared through the processes similar to the processes shown in FIG. 4 to FIG. 8. Then, a bank insulating film 50 made of silicon nitride is prepared and is processed (photolithographic process 5). Next, an organic electroluminescence light emitting layer 51 and an organic electroluminescence top electrode 52 made of aluminum are disposed, and a TFT substrate with an organic electroluminescence element is obtained (FIG. 9).

By preparing the bank insulating film 50, the source-drain electrode 9, the organic electroluminescence light emitting layer 51, and the organic electroluminescence top electrode 52 can be insulated. The organic electroluminescence light emitting portion comprises an organic electroluminescence top electrode 52 grounded to earth, an ITO 16 (3) connected to a power source Es via TFT, and an organic electroluminescence light emitting layer 51 interposed between these two. By supplying electric current to the organic electroluminescence layer 51, light is emitted. Display data sent via the signal line 21 to the pixel 30 as selected according to scan signals sequentially given to the gate line 23 are accumulated in the storage capacitor Cst. Because channel resistance of TFT is changed to match the accumulated voltage, the electric current flowing to the organic electroluminescence light emitting layer 51 can be changed, and gradation is controlled by this change of electric current.

In the Embodiment 2, similarly to the explanation given in connection with FIG. 7 of the Embodiment 1, the gate insulating film 5 is also removed at the same time when the first interlayer insulating film 7 is removed. As a result, as shown in the pixel electrode portion shown in FIG. 8(c), the contact between the source-drain electrode and the gate electrode can be achieved, and the pixel circuit and the peripheral driver circuit to drive the organic electroluminescence element can be deposited on the glass substrate by using the TFT. It is needless to say that the peripheral driver circuit to drive the pixel TFT can be prepared on the glass substrate by using the TFT in the liquid crystal display unit of the Embodiment 1. According to the Embodiment 2, the organic electroluminescence display unit can be prepared through five photolithographic processes, and the organic electroluminescence display unit can be manufactured at lower cost.

### Embodiment 3

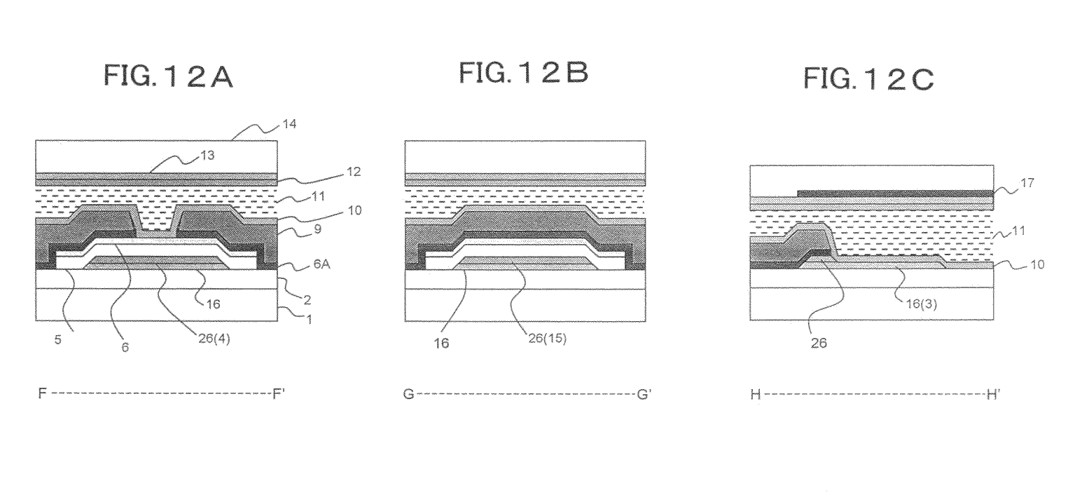

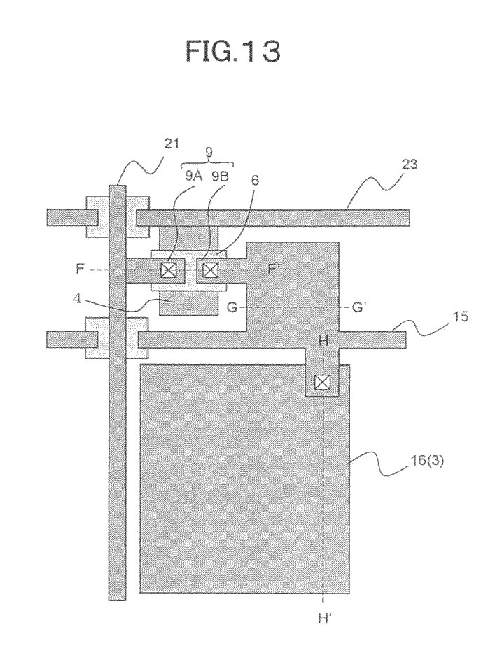

FIG. 12 represents cross-sectional views each showing an essential portion of a pixel, which constitutes a liquid crystal display unit to explain the Embodiment 3 of an image display unit of the present invention. FIG. 13 is a plan view of a pixel in the Embodiment 3 of the invention. The entire arrangement of the liquid crystal display unit of the Embodiment 3 is the same as the arrangement of the Embodiment 1 as shown in FIG. 2. FIG. 12(a) is a cross-sectional view of TFT along the line F-F′ in FIG. 13. FIG. 12(b) is a cross-sectional view of the storage capacitor portion along the line G-G′ in FIG. 13, and FIG. 12(c) is a cross-sectional view along the line H-H′ in FIG. 13.

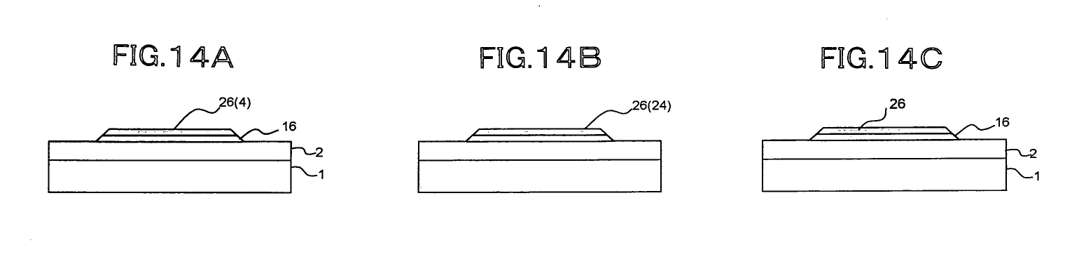

Now, referring to FIG. 14 to FIG. 17, description will be given on a method for manufacturing the liquid crystal display unit of the Embodiment 3. In FIG. 14 to FIG. 17, Figs. (a), (b), and (c) each represents a cross-sectional view of the TFT portion, the storage capacitor portion, and the pixel electrode portion in FIG. 12 respectively. It is needless to say that concrete numerical values given in the explanation are merely an example in this Embodiment.

First, in shown in each of FIGS. 4(a), (b) and (c), an underlying film 2 made of silicon oxide is deposited in film thickness of 300 nm on a glass substrate 1. As a transparent conductive film, ITO is deposited in film thickness of 100 nm as a bottom layer. Then, aluminum (Al) is deposited in film thickness of 150 nm to form a laminated film as a top layer. On it, a photosensitive resist is coated and is dried. By mask exposure, developing and rinsing, a predetermined pattern is given to each of the TFT portion, the storage capacitor portion, and the pixel portion (Photolithographic process 1).

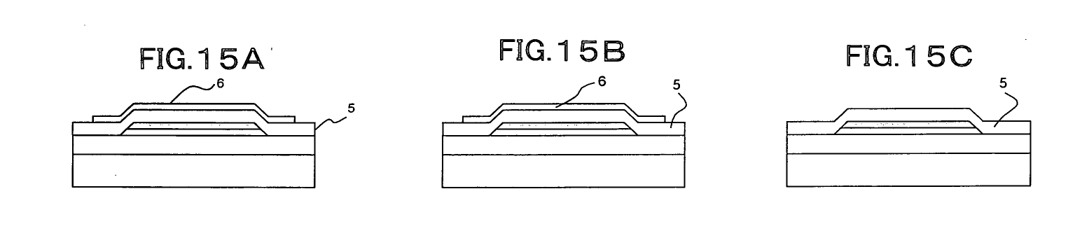

In FIGS. 15(a), (b) and (c), a gate insulating film 5 made of silicon oxide is deposited in film thickness of 100 nm. An amorphous silicon 6 is prepared in film thickness of 50 nm, and this is crystallized by laser annealing. Patterning is performed by photolithographic process, and an island-like polycrystalline silicon film is formed on the TFT portion and the storage capacitor portion (photolithographic process 2).

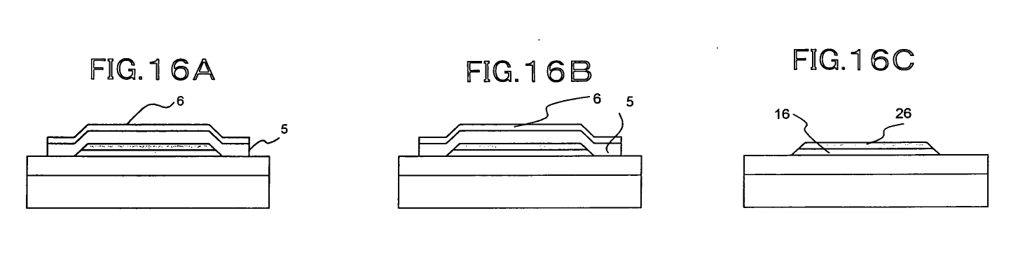

In FIGS. 16(a), (b) and (c), the gate insulating film 5 is removed by using the polycrystalline silicon film 6 with patterning as a mask. In this case, the gate insulating film 5 of the pixel portion can be completely removed, and the aluminum film 26 on the top layer is exposed.

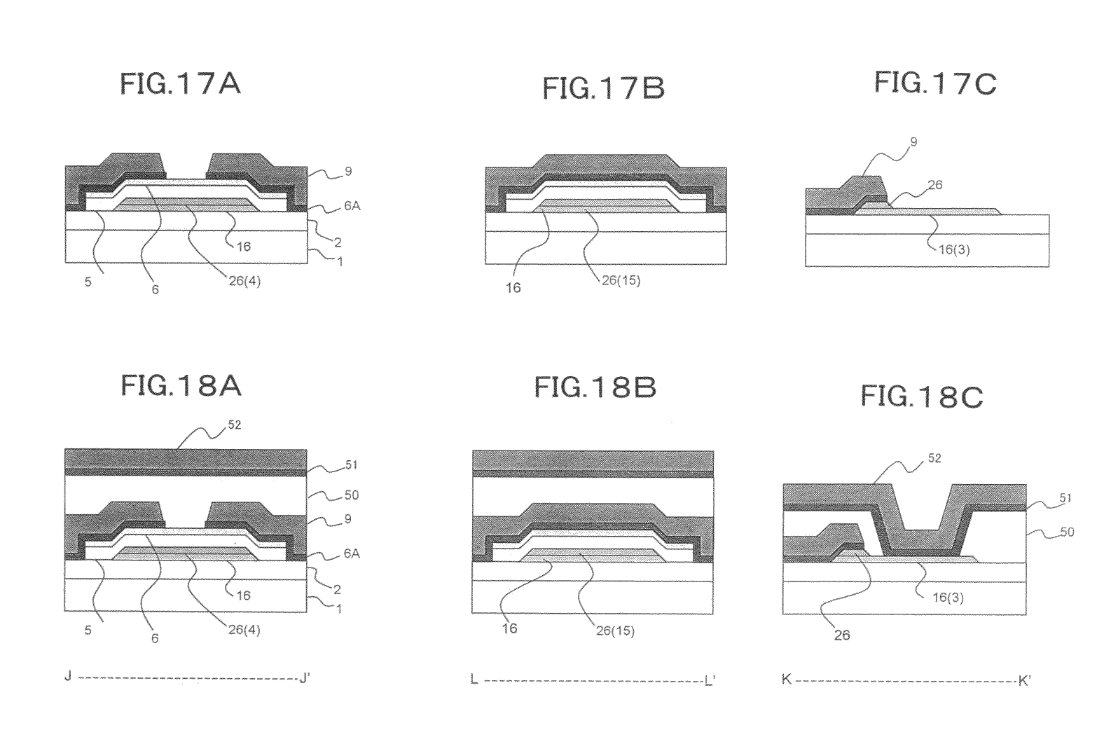

In FIGS. 17(a), (b) and (c), a highly-doped p-type impurity layer 6A is deposited by CVD method (chemical vapor deposition), and a source-drain electrode 9 made of aluminum prepared in film thickness of 500 nm is disposed on the top layer. On it, a photosensitive resist is coated and is dried. By performing mask exposure, developing and rinsing, a resist pattern is prepared. By this resist pattern, the source-drain electrode 9 and the highly-doped impurity layer 6A are processed. Then, the source-drain electrode 9 and the highly-doped p-type impurity layer 6A on TFT channel portion are removed (photolithographic process 3). In this case, at the same time as the removal of the source-drain electrode 9, the metal electrode (aluminum film) on the top layer of the pixel electrode is also removed. Because the top electrodes of the source-drain electrode and the pixel electrode are made of the same metal material, these can be removed at the same time. In case the top electrodes of the source-drain electrode and the pixel electrode are made of different metal materials, after the processing of the source-drain electrode, the top electrode of the pixel electrode can be removed by using the source-drain electrode as a mask similarly to the case of Embodiment 1. The structure of the pixel electrode portion is the same as in the Embodiment 1.

Then, a first orientation film is prepared. A liquid crystal is sealed between the counter substrate and the first orientation film, and a liquid crystal display unit as shown in FIG. 12 can be obtained. Similarly to the Embodiments as described above, a passivation film may be formed on the bottom layer of the first orientation film except the pixel electrode portion, depending on the case.

According to the Embodiment 3, an active substrate for a liquid crystal display unit can be manufactured through three photolithographic processes, and the liquid crystal display unit can be provided at lower cost.

### Embodiment 4

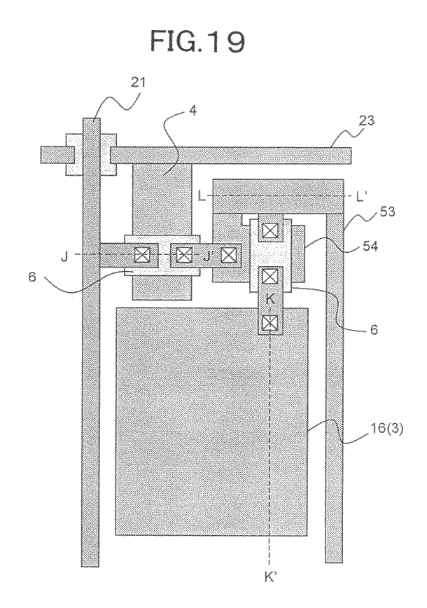

FIG. 18 represents cross-sectional views each showing an essential portion of a pixel, which constitutes an organic electroluminescence display unit to explain the Embodiment 4 of an image display unit of the present invention. FIG. 19 is a plan view to explain an arrangement of a pixel in the Embodiment 4 of the image display unit of the invention. The arrangement of the equivalent circuit of the organic electroluminescence display unit of the Embodiment 4 is the same as the arrangement in the Embodiment shown in FIG. 10. FIG. 18(a) is a cross-sectional view along the line J-J′ in FIG. 19. FIG. 18(b) is a cross-sectional view along the line L-L′ in FIG. 19. FIG. 18(c) is a cross-sectional view along the line K-K′ in FIG. 19.

In the organic electroluminescence display unit of the Embodiment 4, a TFT portion, a storage capacitor portion (Cst), and a pixel electrode portion are prepared through the processes shown in FIG. 14 to FIG. 17 similarly to the Embodiment 3. Then, a bank insulating film 50 made of silicon nitride is prepared and processed (photolithographic process 4). Next, a light emitting layer 51 of the organic electroluminescence display unit and a top electrode 52 made of aluminum are prepared, and an active matrix substrate of the organic electroluminescence display unit is obtained.

According to the Embodiment 4, the active substrate of the organic electroluminescence display unit can be manufactured through four photolithographic processes, and the liquid crystal display unit can be provided at lower cost.

According to the present invention, in the image display unit explained in the Embodiments 1 to 4 as described above, the insulating substrate is not limited to glass substrate, and other types of insulating substrate made of quartz glass or plastics may be used. When quartz glass is used, process temperature can be set to higher temperature. This makes it possible to produce the gate insulating film with higher precision and to improve the reliability of TFT. When the plastic substrate is used, an image display unit with lightweight design and high impact resistance can be obtained.

As described above, as the underlying film, a silicon nitride film or a laminated film of silicon oxide film and silicon nitride film may be used instead of the silicon oxide film. When silicon nitride film is used as the underlying film or when silicon nitride film is used as bottom layer and silicon oxide film is laminated, it is possible to effectively prevent diffusion and intrusion of impurities in the glass substrate into the gate insulating film or the liquid crystal layer.

As the method to crystallize the amorphous silicon, solid phase deposition method by heat annealing may be used or a combination of heat annealing and laser annealing may be used. When heat annealing is used, the flatness of the polycrystalline silicon film can be improved, and pressure resistance of the gate insulating film can be increased. As the semiconductor film, amorphous silicon may be used or microcrystalline silicon may be used. Or, polycrystalline silicon may be used, which is directly deposited by Cat-CVD (catalytic chemical vapor deposition) or reactive thermal CVD. When these methods are adopted, the number of crystallizing processes can be reduced, and this contributes to the improvement of the throughput. Further, when an oxide semiconductor already known is used, light leaking current of TFT can be decreased, and this makes it possible to have higher contrast.

As the materials of barrier metal of the source-drain electrode or gate electrode, the following metal or alloy of these metals may be used: aluminum-neodymium (Al—Nd), titanium (Ti), tungsten-titanium (TiW), titanium nitride (TiN), tungsten (W), chromium (Cr), molybdenum (Mo), tantalum (Ta), niobium (Nb), vanadium (V), zirconium (Zr), hafnium (Hf), platinum (Pt), ruthenium (Ru), etc. Also, as the pixel electrode ITO, a ZnO type transparent electrode already known may be used. When these electrodes are used, the same effects as in the Embodiments 1 to 4 can be obtained.

In the Embodiments 1 to 4 as described above, description has been given on p-channel TFT, while n-channel TFT using n-type impurities may be used. The n-channel TFT has higher performance characteristics than those of p-channel TFT, and a circuit with higher performance characteristics can be obtained. If both n-channel TFT and p-channel TFT are used as CMOS structure, the area of the circuit can be reduced, and power consumption can be decreased further.

1.-7. (canceled)

8. A method for manufacturing an image display unit, said image display unit comprises an active substrate having a multiple of pixels constituted by thin-film transistors on main surface of an insulating substrate, a gate electrode of said thin-film transistor is disposed on the lowermost layer on main surface of said insulating substrate and on a bottom layer of a semiconductor film to make up an active layer of said thin-film transistor, and said source-drain electrode is designed as a bottom gate type connected to an upper portion of said semiconductor, wherein said method comprises:
a step of depositing a laminated electrode film having a transparent conductive film as the bottom layer and a metal film as the top layer at least over the entire pixel area on said insulating substrate;
a step of processing semiconductor to form a gate insulating film to cover said laminated electrode film, and of forming a semiconductor film thereon and depositing said semiconductor film processed in island-like shape on an area to dispose said thin-film transistor;
a step of processing an interlayer insulating film after depositing an interlayer insulating film to cover said semiconductor film processed by said semiconductor processing, and of removing said interlayer insulating film on a source-drain electrode and said pixel portion of said thin-film transistor by processing said interlayer insulating film;
a step of depositing a metal film to form a metal film for the source-drain electrode over the entire region including the source-drain electrode region and said pixel region of said thin-film transistor as removed by said step of processing said interlayer insulating film; and
a step of depositing a source-drain electrode on said source-drain electrode region on said thin-film transistor forming area by processing said metal film and removing said metal film, and leaving a part to be turned to a metal film for connection on a part of said laminated electrode film of said pixel region and having a pixel electrode by leaving only said transparent conductive film.

9. A method for manufacturing an image display unit according to claim 8, wherein ITO is used on a bottom layer of said laminated electrode film.

10. A method for manufacturing an image display unit according to claim 8, wherein a transparent conductive film of tin oxide type is used on a bottom layer of said laminated electrode film.

11. A method for manufacturing an image display unit according to claim 9, wherein aluminum or aluminum-neodymium alloy is used on a top layer of said laminated electrode film.

12. A method for manufacturing an image display unit according to claim 9, wherein one of titanium, tungsten-titanium, titanium nitride, tungsten, chromium, molybdenum, tantalum, niobium, vanadium, zirconium, hafnium, platinum, ruthenium, or an alloy of these metals is used on a top layer of said laminated electrode film.

13. A method for manufacturing an image display unit according to claim 8, wherein said gate insulating film and said semiconductor film formed on a top layer of said laminated electrode film and a storage capacitor formed with said metal film are prepared on said pixel area.

14. A method for manufacturing an image display unit according to claim 8, wherein said method further comprises a step of depositing an orientation film to give liquid crystal orientation control ability to said orientation film after coating an orientation film material on a top layer of said pixel electrode.

15. A method for manufacturing an image display unit according to claim 14, wherein said method further comprises a step of sealing to attach a color filter substrate via a liquid crystal layer on said active substrate where said orientation film is deposited.

16. A method for manufacturing an image display unit according to claim 15, wherein said counter substrate has a counter electrode.

17. A method for manufacturing an image display unit according to claim 8, wherein said method further comprises a step of depositing an organic electroluminescence light emitting layer by depositing an organic electroluminescence light emitting layer on a top layer of said pixel electrode.

18. A method for manufacturing an image display unit according to claim 17, wherein said method further comprises a step of depositing an electrode film, said electrode film being the other of the electrodes to interpose said organic electroluminescence light emitting layer between the electrode film, i.e. the other of the electrodes, and said pixel electrode, i.e. one of the electrodes, to cover the entire pixel area of said plurality of pixels on a top layer of said organic electroluminescence light emitting layer.

19. A method for manufacturing an image display unit according to claim 8, wherein said method further comprises a step of using a glass substrate as said insulating substrate, and of depositing an underlying film on main surface of said glass substrate before the process of depositing said laminated electrode film.

20. A method for manufacturing an image display unit according to claim 19, wherein said step of depositing said underlying film is either a step of depositing a silicon oxide film or a silicon nitride film or a laminated film of silicon oxide and silicon nitride.
